(19) United States
(12) Patent Application Publication
(10) Pub. No.: US 2008/0118005 A1
(43) Pub. Date: May 22, 2008

(54) RECEIVING APPARATUS AND RECEIVING METHOD

(75) Inventor: Kensuke Yasuma, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/939,399

(22) Filed: Nov. 13, 2007

(30) Foreign Application Priority Data
Nov. 22, 2006 (JP) 2006-315714

(51) Int. Cl. H03K 9/00

(52) U.S. Cl. 375/316

(57) ABSTRACT

A receiving apparatus holds identification information used by a transferring device on a transmission medium to identify transmission data to be transferred to the receiving apparatus. The receiving apparatus outputs the received identification information to be inputted to a transmitting apparatus via a medium different from the transmission medium. The receiving apparatus receives data which is transferred by the transferring device after transmitted from the transmitting apparatus that has inputted the identification information.

### BACKGROUND OF THE INVENTION

1. Field of the Invention

The present invention relates to a receiving apparatus and receiving method.

2. Description of the Related Art

When transmitting data from a transmitting apparatus to a receiving apparatus via the Internet, the data may be routed by a router which connects the receiving apparatus to the Internet.

In terms of security and the like, it is sometimes desirable to limit (or inhibit) reception by the receiving apparatus.

Japanese Patent Laid-Open No. 2005-94264 discloses a method of requesting and accepting connection of a servent to a logical network using the servent ID of the servent and that of a seed servent. According to this method, the servent ID of a target servent and that of a seed servent serving as the destination of a logical network connection request are set in advance.

That is, according to the prior art, information (e.g., the IP address, port number, identifier, and authentication information of a receiving apparatus) need to be set in a transmitting apparatus so that the receiving apparatus can receive data.

Setting such information is complicated and difficult. Especially, it is difficult and inconvenient to make the settings through many inputs in a compact portable device such as a camera whose user interface is poor.

It is also troublesome and difficult to make reception limitation and inhibition settings.

### SUMMARY OF THE INVENTION

The present invention realizes to allow easily transmittable data.

A receiving apparatus according to the present invention comprises a receiving unit adapted to receive, via a transmission medium, transmission data transmitted from a transmitting apparatus; a setting unit adapted to set, in a transferring device on the transmission medium, first identification information to be used by the transferring device to identify transmission data to be transferred to the receiving unit, and second identification information to be used by the receiving unit to identify transmission data transmitted to the receiving unit; and an output unit adapted to output the received first identification information to be inputted to the transmitting apparatus via a medium different from the transmission medium. The receiving unit identifies, based on the second identification information, transmission data which is assigned with the second identification information and transferred by the transferring device after transmitted from the transmitting apparatus that has inputted the first identification information, and the receiving unit receives the identified transmission data.

A receiving apparatus according to the present invention comprises a receiving unit adapted to receive, via a transmission medium, transmission data transmitted from a transmitting apparatus, and receives, by the receiving unit from a communication apparatus on the transmission medium, identification information used by a transferring device on the transmission medium to identify transmission data to be transferred to the receiving unit. The receiving apparatus according to the present invention further comprises an output unit adapted to output the received identification information to be inputted to the transmitting apparatus via a medium different from the transmission medium. The receiving unit receives the transmission data transferred by the transferring device after transmitted from the transmitting apparatus that has inputted the identification information.

Further features of the present invention will become apparent from the following description of exemplary embodiments (with reference to the attached drawings).

### BRIEF DESCRIPTION OF THE DRAWINGS

FIG. 1 is a block diagram showing the configuration of a network system according to the first embodiment;

FIG. 2 is a block diagram showing a system when a network control apparatus 101 according to an embodiment of the present invention is implemented using a PC (Personal Computer);

FIG. 3 is a block diagram showing an internal module configuration according to the first embodiment;

FIG. 4 is a flowchart showing a sequence upon detecting connection of a storage medium;

FIG. 5 is a flowchart showing a sequence upon detecting disconnection of a storage medium;

FIG. 6 is a table showing logical network connection setting information stored in a storage medium;

FIG. 7 is a table showing storage information of a network control apparatus and storage medium corresponding to a given state;

FIG. 8 is a block diagram showing the configuration of a network system according to the second embodiment;

FIG. 9 is a block diagram showing a module configuration according to the second embodiment;

FIG. 10 is a table showing information stored in a storage medium; and

FIG. 11 is a table showing information stored in an information storage server.

### DESCRIPTION OF THE EMBODIMENTS

### First Embodiment

The first embodiment will be described in detail below with reference to the accompanying drawings.

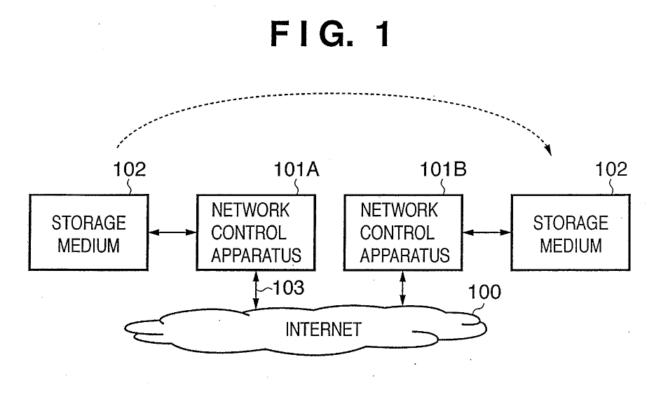

The configuration of a network system according to the first embodiment will be described with reference to FIG. 1.

In FIG. 1, Internet 100 may be implemented by a network such as a single WAN (Wide Area Network), LAN (Local Area Network), or ad hoc network. The Internet 100 may also be implemented by combining necessary numbers of WANs, LANs, and ad hoc networks. The Internet in the first embodiment is merely an example, and another communication network or a combination of communication networks is also available. In a given form, a home router exists at a position 103 between a network control apparatus 101A and the Internet 100.

The network control apparatus 101A and a network control apparatus 101B (transmitting apparatus, receiving apparatus, and communication apparatus) control a logical network.

A storage medium 102 can communicate by short distance wireless communication. The storage medium may also communicate by another communication means (e.g., USB (Universal Serial Bus) or WUSB (Wireless Universal Serial Bus)), or infrared communication. The storage medium may also be formed from a communication apparatus having a storage device. In other words, the storage medium 102 may also be incorporated in the network control apparatus 101B. The storage medium in the first embodiment is merely an example, and may be a combination of storage devices.

In FIG. 1, the two network control apparatuses 101A and 101B are connected. However, the number of network control apparatuses is not limited to two, and three or more network control apparatuses may also be connected.

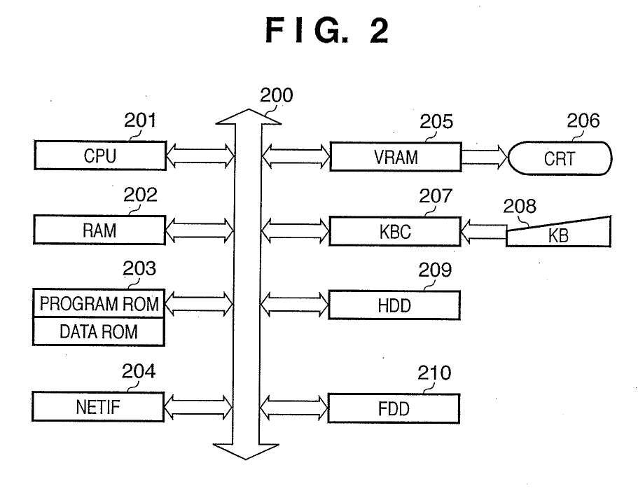

The network control apparatuses 101A and 101B according to the first embodiment will be explained with reference to FIG. 2. The network control apparatuses 101A and 101B are not limited to computer systems such as a PC (Personal Computer). For example, the network control apparatuses 101A and 101B include various home electrical appliances such as a television set incorporating a computer, game machines having a communication function, and cell phones. The network control apparatuses 101A and 101B can be formed from terminals having a communication function of communicating with another network control apparatus, or a combination of them.

A central processing unit (to be referred to as a CPU hereinafter) 201 controls the computer system.

A random access memory (to be referred to as a RAM hereinafter) 202 functions as the main memory of the CPU 201, the area of an executing program, and the execution area and data area of the program.

A read only memory (to be referred to as a ROM hereinafter) 203 stores the operation procedures of the CPU 201. The ROM 203 comprises a program ROM which stores an operating system (OS) serving as a system program for controlling the devices of the computer system, and a data ROM which stores information necessary to operate the system. An HDD 209 (to be described later) may also be used instead of the ROM 203.

A network interface (to be referred to as a NETIF hereinafter) 204 controls data transfer between computer systems via a network, and diagnoses the connection status. The NETIF 204 communicates via the Internet 100, and communicates with the storage medium 102.

A video RAM (to be referred to as a VRAM hereinafter) 205 rasterizes an image to be displayed on the screen of a CRT 206 (to be described later) representing the running state of the computer system, and controls the display.

The display device or display 206 will be referred to as a CRT.

A controller 207 controls an input signal from an external input device 208 (to be described later).

The external input device 208 accepts an operation to the computer system by its user. The external input device 208 is, e.g., a keyboard.

Reference numeral 209 denotes a storage device such as a hard disk (HDD). The storage device 209 saves data such as application programs and image information. An application program in the first embodiment is, e.g., a software program which executes various kinds of security protocol control according to the first embodiment. Some of the computer programs stored in the storage device 209 will be described later with reference to flowcharts. The storage device 209 stores the computer programs so that the computer CPU 201 can read them out.

An external I/O device 210 inputs/outputs data to/from a storage medium in a CD-ROM driver or the like, and is used to read out the above-mentioned application program from a medium. The external I/O device 210 will be referred to as an FDD. The application programs and data stored in the storage device 209 can also be used by storing them in the FDD 210.

An I/O bus (address bus, data bus, and control bus) 200 connects the above-described units.

The network control apparatus 101A in FIG. 2 is a receiving apparatus. The NETIF 204 receives, via the Internet 100 serving as a transmission medium, data which is transmitted from the network control apparatus 101B serving as a transmitting apparatus and routed by the home router. The NETIF 204 outputs information to the storage medium 102 which is a medium different from the Internet 100 serving as the transmission medium. As will be described later, the CPU 201 sets the home router which is a router for connecting the network control apparatus 101A to the Internet 100.

As will be described later, the NETIF 204 receives information from a STUN (Simple Traversal of UDP through NAT (Network Address Translation)) server (not shown) serving as a communication apparatus on the Internet 100.

The NETIF 204 receives information from the storage medium 102. The CPU 201 limits data reception by the NETIF 204.

The network control apparatus 101B in FIG. 2 is a transmitting apparatus. The CPU 201 transmits data from the NETIF 204 to the network control apparatus 101A.

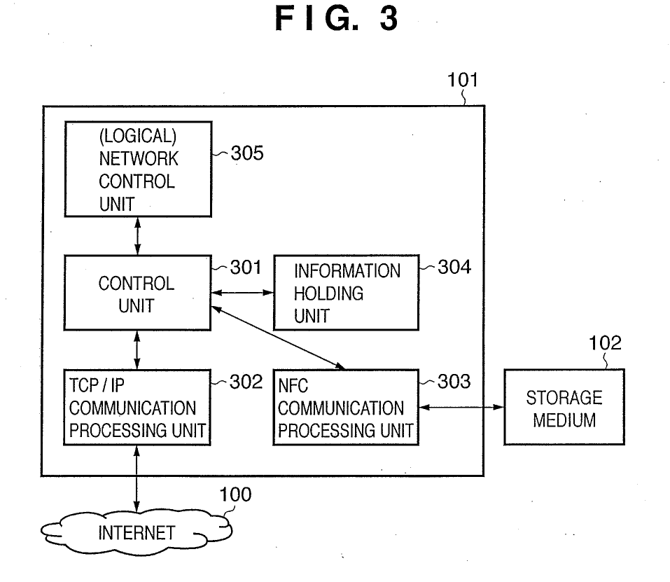

A module configuration in the network control apparatuses (receiving apparatus, transmitting apparatus, and communication apparatus) 101A and 101B according to the first embodiment will be explained with reference to FIG. 3.

A control unit 301 instructs a network control unit 305 to control a logical network, and performs logical network connection acceptance processing. Also, the control unit 301 transmits logical network connection setting information to a TCP/IP communication processing unit 302, and receives logical network connection setting information from the TCP/IP communication processing unit 302. The control unit 301 transmits logical network connection setting information to an NFC communication processing unit 303, and receives logical network connection setting information from the NFC communication processing unit 303. Details of the connection setting information will be described later.

The TCP/IP communication processing unit 302 performs TCP/IP communication. The first embodiment exemplifies TCP/IP communication, but the processing may also be achieved using another wired or wireless communication means.

The NFC communication processing unit 303 performs NFC communication. The first embodiment exemplifies NFC communication, but the processing may also be achieved using another wireless or wired communication means. The TCP/IP communication processing unit 302 and NFC communication processing unit 303 transmit and receive information via different media.

An information holding unit 304 holds logical network connection acceptance information and logical network connection setting information. Details of the logical network connection acceptance information and logical network connection setting information will be described later.

The network control unit 305 controls and manages a logical network.

The first embodiment hardly depends on the logical network format. In the first embodiment, the logical network can be formed from a network of layer 3 VPN (Virtual Private Network), layer 2 VPN, and a distributed hash table. The logical network can also be formed from a peer-to-peer connection network, an application layer network, or the like.

In FIG. 3, the information holding unit 304 corresponds to the RAM 202 in FIG. 1, and the TCP/IP communication processing unit 302 and NFC communication processing unit 303 correspond to the NETIF 204 in FIG. 2. In FIG. 2, it is also possible to arrange a NETIF 204A in correspondence with the TCP/IP communication processing unit 302 and a NETIF 204B in correspondence with the NFC communication processing unit 303. In FIG. 3, the control unit 301 and network control unit 305 correspond to the CPU 201 in FIG. 2. The control unit 301 and network control unit 305 correspond to some functions of the CPU 201. In FIG. 3, the control unit 301 may also function as the network control unit 305.

The network control apparatus 101A in FIG. 1 is a receiving apparatus. In the network control apparatus 101A serving as a receiving apparatus, the TCP/IP communication processing unit 302 receives, via the Internet 100 serving as a transmission medium, data which is transmitted from the network control apparatus 101B serving as a transmitting apparatus and routed by the home router. The control unit 301 sets the home router which is a router for connecting the network control apparatus 101A to the Internet 100. The NFC communication processing unit 303 outputs information to the storage medium 102 serving as a medium different from the Internet 100.

The TCP/IP communication processing unit 302 receives information from a STUN (Simple Traversal of UDP through NAT) server (not shown) serving as a communication apparatus on the Internet 100.

The NFC communication processing unit 303 receives information from the storage medium 102. The CPU 201 limits reception of transmission data by the TCP/IP communication processing unit 302.

The network control apparatus 101B in FIG. 1 is a transmitting apparatus. The CPU 201 transmits data from the TCP/IP communication processing unit 302 to the network control apparatus 101A.

An example of building a logical network by the network control apparatus (receiving apparatus) 101A and network control apparatus (transmitting apparatus) 101B in FIG. 1 will be explained.

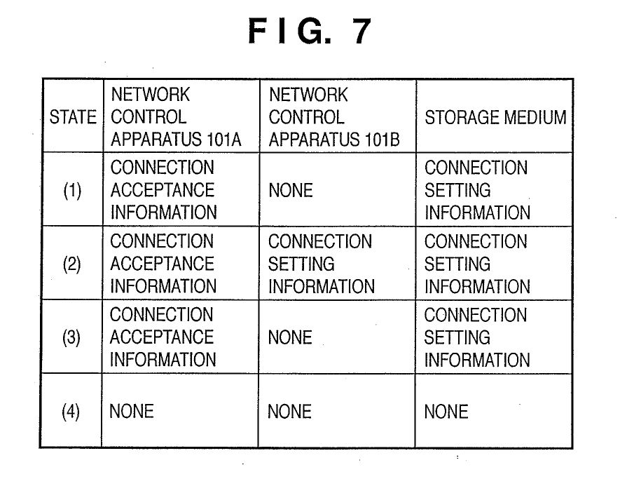

FIG. 7 shows an example of information elements in the network control apparatuses 101A and 101B and the storage medium 102. The network control apparatuses 101A and 101B and the storage medium 102 in FIG. 7 correspond to those in FIG. 1.

When the network control apparatus 101A detects that the storage medium 102 has been connected, it acquires connection setting information from the storage medium 102.

If the storage medium 102 does not hold connection setting information, the network control apparatus 101A generates connection acceptance information and connection setting information. The network control apparatus 101A checks whether network settings compliant with the generated connection setting information are possible. Details of this check will be explained later. Then, the network control apparatus 101A writes the generated connection setting information in the storage medium 102. After performing logical network connection acceptance start processing, the network control apparatus 101A notifies a network control apparatus (not shown) connected to a logical network of the start of accepting connection to the logical network. Details of the connection acceptance start processing will be described later. A network control apparatus at the connection acceptance start notification destination may not exist.

A state after the end of the series of operations is state (1) in FIG. 7. In state (1) of FIG. 7, connection acceptance information is recorded in the network control apparatus 101A, connection setting information is recorded on the storage medium 102, and no information (connection setting information) is recorded in the network control apparatus 101B. Details of the connection acceptance information and connection setting information will be described later.

When the network control apparatus 101A detects that the storage medium 102 has been disconnected, it determines whether logical network connection setting information exists, and then ends the processing. In this case, since no connection setting information exists, the processing ends.

When the network control apparatus 101B detects that the storage medium 102 has been connected, it acquires connection setting information from the storage medium 102. If the storage medium 102 holds the connection setting information, the network control apparatus 101B reads it out from the storage medium 102 and stores it. Then, the network control apparatus 101B determines whether the network control apparatus 101B itself has generated the connection setting information.

If the network control apparatus 101B itself has not generated the connection setting information, it determines whether to start connection to a logical network. When the network control apparatus 101B is not connected to a logical network corresponding to the connection setting information, it starts connection to the logical network. At the start of connection to the logical network, the network control apparatus 101B performs logical network connection start processing, and notifies a network control apparatus connected to the logical network of the start of connection to the logical network. The network control apparatus connected to the logical network is the network control apparatus 101A (and a network control apparatus (not shown)). In this manner, the network control apparatus 101B is a transmitting apparatus. The network control apparatus 101B receives connection setting information from the storage medium 102. If the network control apparatus 101B itself has not generated the input connection setting information, it adds destination information to transmission data and transmits the resultant data to notify the start of connection. The destination information is included in the connection setting information input from the storage medium 102.

A state after the end of the series of operations is state (2) in FIG. 7. In state (2) of FIG. 7, the network control apparatus 101A stores connection acceptance information, and the network control apparatus 101B and storage medium 102 store connection setting information.

When the network control apparatus 101B detects that the storage medium 102 has been disconnected, it determines whether it is connected to the logical network. If the network control apparatus 101B is connected to the logical network, it determines whether to end the connection to the logical network. The network control apparatus 101B ends the connection unless it is set from a user interface or another program to continue connection of the logical network. At the end of the connection to the logical network, the network control apparatus 101B notifies a network control apparatus connected to the logical network that the network control apparatus 101B has been disconnected from the logical network. The network control apparatus connected to the logical network is the network control apparatus 101A (and a network control apparatus (not shown)). Thereafter, the network control apparatus 101B deletes the stored connection setting information, and ends the processing.

A state after the end of the series of operations is state (3) in FIG. 7. In state (3) of FIG. 7, the network control apparatus 101A stores connection acceptance information, the storage medium 102 stores connection setting information, and the network control apparatus 101B does not store information (connection setting information).

When the network control apparatus 101A detects that the storage medium 102 has been disconnected, it acquires connection setting information from the storage medium 102. If the storage medium 102 stores connection setting information and the network control apparatus 101A has generated the stored connection setting information, the network control apparatus 101A determines whether to delete the connection setting information. If deletion of the connection setting information is designated with a button or by a program or the like, the network control apparatus 101A deletes the connection setting information. At this time, the network control apparatus 101A deletes corresponding network settings from it, and deletes corresponding connection setting information from the storage medium 102. The network control apparatus 101A ends the acceptance of connection to the logical network, and deletes (invalidates) connection acceptance information from the network control apparatus 101A. If another network control apparatus is connected to the logical network, the network control apparatus 101A notifies the connected network control apparatus of the end of accepting connection to the logical network. The network control apparatus connected to the logical network is a network control apparatus (not shown). A state after the end of the series of operations is state (4) in FIG. 7. In state (4) of FIG. 7, the network control apparatus 101A does not store information (connection acceptance information), the network control apparatus 101B does not store information (connection setting information), and the storage medium 102 does not store information (connection setting information).

As described above, the network control apparatus 101A outputs, to the storage medium 102, connection setting information to be input to the network control apparatus 101B serving as a transmitting apparatus, and receives data transmitted from the network control apparatus 101B. Upon receiving the connection setting information from the storage medium 102, the network control apparatus 101A ends the acceptance of connection, and limits subsequent data reception from the Internet 100.

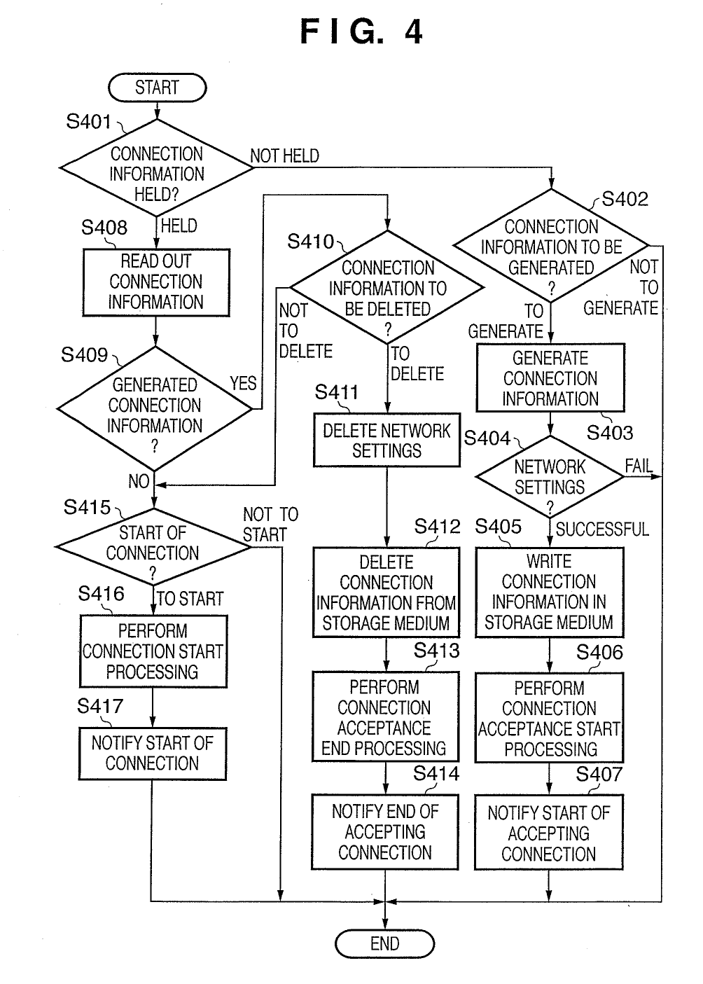

A sequence upon detecting connection of a storage medium in the network control apparatuses 101A and 101B according to the first embodiment will be explained with reference to the flowchart of FIG. 4. FIG. 4 shows part of a computer program stored in the HDD 209 or FDD 210. The computer CPU 201 reads out the program from the HDD 209 or FDD 210, and executes an operation corresponding to the flowchart of FIG. 4. The HDD 209 or FDD 210 is a storage medium which stores the program so that the CPU 201 can read it out.

In step S401, it is determined whether the storage medium 102, connection of which has been detected, holds connection setting information. If it is determined in step S401 that the storage medium 102, connection of which has been detected, does not hold connection setting information, the process proceeds to step S402. If it is determined in step S401 that the storage medium 102, connection of which has been detected, holds connection setting information, the process proceeds to step S408.

In step S402, it is determined whether to generate connection setting information. In a network control apparatus (e.g., the network control apparatus 101A) which accepts connection to a logical network, the control unit 301 has a function of generating connection setting information, and generates it. In a network control apparatus which requests connection to a logical network but does not accept connection to it, the control unit 301 does not have the function of generating connection setting information, and thus does not generate it. In a network control apparatus which accepts connection to a logical network, it is also possible to input an instruction to the control unit 301 about generation of connection setting information from a user interface or another program, and determine whether to generate connection setting information. In all network control apparatuses, connection setting information may also be generated. In this case, the determination in step S402 is unnecessary. If it is determined in step S402 to generate connection setting information, the process proceeds to step S403. If it is determined in step S402 not to generate connection setting information, the process ends.

In step S403, connection setting information, and connection acceptance information for accepting connection to a logical network are generated, and the process proceeds to step S404. In the first embodiment, the connection acceptance information includes authentication information corresponding to the connection setting information. The logical network connection setting information includes information such as the IP address, port number, protocol, authentication method, and password of a node (in the above-described example, the network control apparatus 101A) permitted to connect to the logical network. The IP address of the node permitted to connect to the logical network may be a multicast address or anycast address. When network control apparatuses are distributed, the IP address may be a unicast address different from the address of a node which generates connection setting information.

In step S404, it is determined whether network settings compliant with the logical network connection setting information are possible. In step S404, the control unit 301 determines whether the port number of a program which accepts connection setting information is available, and whether to accept a compliant authentication method. Further, the control unit 301 determines whether the port number of the home router can be set. The home router exists at the position 103 in FIG. 1. In the first embodiment, the home router is defined as a UPnP Internet Gateway Device, and can determine, from an external message, whether the port number is changeable. If it is determined in step S404 that network settings compliant with the logical network connection setting information are possible, the process proceeds to step S405. If it is determined in step S404 that network settings compliant with the logical network connection setting information are impossible, the process ends.

In step S405, the logical network connection setting information is written in the storage medium 102, and the process proceeds to step S406. In step S406, logical network connection acceptance start processing is performed, and the process proceeds to step S407. In the connection acceptance start processing, the control unit 301 opens a listening socket for accepting connection to the logical network.

When setting the port number of the home router, AddPortMapping is done for the UPnP Internet Gateway Device to set the port number of the UPnP Internet Gateway Device. This port number is that in the connection setting information generated in step S403. Based on the AddPortMapping instruction, conversion between the first IP address and port number, and the second IP address and port number is set.

The first IP address and port number, conversion of which is set, are the IP address and port number of the network control apparatus 101A that are laid open to the WAN (network control apparatus 101B) of the home router. The home router has the Internet Gateway Device function. The second IP address and port number are the IP address and port number of the network control apparatus 101A that are laid open to the LAN (network control apparatus 101A). Hence, the port number in the connection setting information generated in step S403 is that of the WAN (network control apparatus 101B) of the home router. That is, the IP address and port number included in the connection setting information are those of a network control apparatus that are laid open to the WAN of the home router. The IP address and port number included in the connection acceptance information are those of a network control apparatus that are laid open to the LAN (network control apparatus 101A) of the home router.

More specifically, the network control apparatus 101A is a receiving apparatus, and receives data transmitted from the network control apparatus 101B serving as a transmitting apparatus via the Internet 100 serving as a transmission medium. The network control apparatus 101A sets the following first identification information and second identification information in the home router (router) which connects the network control apparatus 101A to the Internet 100.

The home router (router) uses the first identification information to identify transmission data to (the TCP/IP communication processing unit 302 of) the network control apparatus 101A. More specifically, the first identification information is formed from the IP address and port number of the network control apparatus 101A that are laid open to the WAN. The (TCP/IP communication processing unit 302 of) network control apparatus 101A uses the second identification information to identify transmission data to (the TCP/IP communication processing unit 302 of) the network control apparatus 101A. More specifically, the second identification information is formed from the IP address and port number of the network control apparatus 101A that are laid open to the LAN. Upon receiving data including the first identification information (IP address and port number laid open to the WAN) from the Internet 100 (from the WAN), the home router determines that the data is addressed to the network control apparatus 101. In this case, the home router adds the second identification information (IP address and port number laid open to the LAN) (changes the destination address and port number), and transmits the resultant data to the LAN (network control apparatus 101A).

Upon receiving the data including the second identification information, (the TCP/IP communication processing unit 302 of) the network control apparatus 101A determines that the data is addressed to (the TCP/IP communication processing unit 302 of) the network control apparatus 101A.

The network control apparatus 101A outputs, to the storage medium 102, the first identification information input to the network control apparatus 101B via the storage medium 102 serving as a medium different from the Internet 100. Based on the second identification information, the network control apparatus 101A identifies data which is routed by the home router (router) after transmitted from the network control apparatus 101B that has received the first identification information. Then, the network control apparatus 101A receives the data.

In the first embodiment, the port number of the UPnP Internet Gateway Device is set. Instead, NAT traversal of the home router by STUN (Simple Traversal of UDP through NAT) or the like may also be set. To execute STUN, a STUN server having two global IP addresses is necessary on the Internet. In other words, the STUN server is a communication apparatus on the Internet (communication medium) 100. The STUN server uses two global IP addresses and two port numbers. The network control apparatus 101A has a STUN client (operates as a STUN client) for communicating with the STUN server.

The STUN client (network control apparatus 101A) and STUN server exchange UDP test messages using one IP address and one port number of the STUN client and two global IP addresses and two port numbers of the STUN server. The test messages allow determining the type of NAT. For Cone NAT, it is determined that network settings are possible by NAT traversal based on STUN. To implement NAT traversal, the STUN client and STUN server periodically exchange UDP messages so as to hold a NAT cache.

The STUN client acquires an IP address and port number laid open to the WAN (network control apparatus 101B) of the home router from the STUN server. A communication node (network control apparatus 101B) which accesses the STUN client from the WAN (Internet 100 side) of the home router at the position 103 in FIG. 1 starts UDP communication to the IP address and port number acquired from the STUN server. As a result, NAT traversal of the home router can be achieved.

More specifically, the network control apparatus 101A receives data transmitted from the network control apparatus 101B serving as a transmitting apparatus via the Internet 100 serving as a transmission medium. The network control apparatus 101A receives identification information (the IP address and port number of the network control apparatus 101A that are laid open to the WAN) from the STUN server serving as a communication apparatus on the Internet 100. The home router (router) uses this identification information to identify data transmitted from the network control apparatus 101B to (the TCP/IP communication processing unit 302 of) the network control apparatus 101A. More specifically, this identification information is formed from the IP address and port number of the network control apparatus 101A that are laid open to the WAN.

The home router (router) connects the network control apparatus 101A to the Internet 100. Upon receiving the IP address and port number (identification information) of the network control apparatus 101A that are laid open to the WAN, the home router determines that the data is addressed to the network control apparatus 101A.

The network control apparatus 101A outputs, to the storage medium 102, the identification information (the IP address and port number of the network control apparatus 101A that are laid open to the WAN) inputted to the network control apparatus 101B via the storage medium 102. The storage medium 102 is a medium different from the Internet 100. The network control apparatus 101A receives data which is routed by the home router (router) after transmitted from the network control apparatus 101B that has received the identification information.

The IP address of the WAN (network control apparatus 101B) in the home router cannot be designated regardless of whether to set the port number of the UPnP Internet Gateway Device or to set STUN. When setting the port number of the UPnP Internet Gateway Device, the port number of the WAN can be designated. However, when setting STUN, the port number of the WAN cannot be designated. The network control apparatus 101A does not make any setting of the home router. The network control apparatus 101A saves, in the storage medium 102, the IP address and port number of the WAN of the entry home router that are generated between the STUN server and the STUN client and acquired from the STUN server using STUN.

In step S407, the start of accepting connection to the logical network is notified, and the process ends. A node or processor which requires connection acceptance start information is notified of the start. The notification destination may also be the unicast address of a node which requires the logical network connection acceptance start information, or a multicast address for advertising the logical network connection acceptance start information. This notification destination is a network control apparatus (not shown) connected to the logical network together with the network control apparatus 101A. In some cases, the network control apparatus at the notification destination may not exist.

In step S408, the logical network connection setting information is read out from the detected storage medium 102, and the process proceeds to step S409. This connection setting information is held in the information holding unit 304.

In step S409, it is determined whether the readout logical network connection setting information is one generated by a corresponding network control apparatus. The corresponding network control apparatus is a network control apparatus associated with a network control apparatus which has generated the logical network connection setting information. The network control apparatus associated with a network control apparatus which has generated the logical network connection setting information is not limited to the network control apparatus itself which has generated the logical network connection setting information. In other words, the network control apparatus 101A which generates logical network connection setting information may be different from a network control apparatus which accepts logical network connection setting information. This means that the functions of a network control apparatus are divided and distributed on a network.

Assume that connection setting information α generated by the network control apparatus 101A includes the address and password of a network control apparatus 101C (not shown). The network control apparatus 101B starts connection to a logical network by using the logical network connection setting information α. Thus, the network control apparatus 101B requests the network control apparatus 101C to start connection to the logical network.

In step S409, the network control apparatus 101C branches to “NO” in step S409. In a form in which the network control apparatuses 101A and 101C refer to the same database or the like, the network control apparatus 101C recognizes that the network control apparatus 101A has generated the connection setting information, and the process branches to “YES”.

Also when multicast (or anycast) is used, a network control apparatus which has generated connection setting information may be different from one which accepts a connection request. That is, when a connection request is multicast to network control apparatuses which accept connection to a given logical network, the connection request reaches them. In this case, a network control apparatus which has generated connection setting information may be different from one which accepts the connection request.

By comparing an address or the like included in connection setting information, it can be determined whether the connection setting information is information associated with a network control apparatus which has generated the logical network connection setting information.

If it is determined in step S409 that the readout logical network connection setting information has been generated by a corresponding network control apparatus, the process proceeds to step S410. If it is determined in step S409 that the readout logical network connection setting information has not been generated by a corresponding network control apparatus, the process proceeds to step S415.

In step S410, it is determined whether to delete the logical network connection setting information. In a network control apparatus which accepts connection to the logical network, an instruction about deletion of connection setting information is input to the control unit 301 from a user interface or another program. If there is no deletion instruction, no connection setting information is deleted. However, the connection setting information may also be deleted without any deletion instruction. If it is determined in step S410 to delete the logical network connection setting information, the process proceeds to step S411. If it is determined in step S410 not to delete the logical network connection setting information, the process proceeds to step S415.

In step S411, network settings compliant with the logical network connection setting information are deleted, and the process proceeds to step S412. The network settings deleted in step S411 are the port number and the like of the home router on the network that have been set by the logical network connection start processing in step S406. That is, when the (connection setting) information (first destination information) output in step S405 matches the (connection setting) information (second destination information) input in step S408, reception of transmission data by the TCP/IP communication processing unit 302 is limited. The (TCP/IP communication processing unit 302 of) network control apparatus 101A does not receive data transmitted from a network control apparatus on the Internet 100 to the network control apparatus 101A.

If the control unit 301 has set the port number of the home router in step S406, the port number setting of the UPnP Internet Gateway Device is deleted in step S406. The deletion is achieved by DeletePortMapping in the UPnP Internet Gateway Device. If NAT traversal of the home router by STUN or the like is set in step S406, the processing to set NAT traversal of the home router ends in step S411.

That is, when the (connection setting) information (first destination information) output in step S405 matches the (connection setting) information (second destination information) input in step S408, transfer of transmission data to (the TCP/IP communication processing unit 302 of) the network control apparatus 101A via the home router is limited. The home router is a device on the network. After that, based on the first destination information, the home router does not transfer data transmitted from a network control apparatus on the Internet 100 to the network control apparatus 101A.

In step S412, the logical network connection setting information is deleted from the storage medium 102 (connection setting information (identification information) in the storage medium 102 is invalidated), and the process proceeds to step S413. In step S413, logical network connection acceptance end processing is executed to delete corresponding logical network connection acceptance information generated in step S403 from the information holding unit 304. Then, the process proceeds to step S414.

In step S414, the end of accepting connection to the logical network is notified, and the process ends. A node or processor which requires connection acceptance end information is notified of the end. The notification destination may also be the unicast address of a node which requires the logical network connection acceptance end information, or a multicast address for advertising the logical network connection acceptance end information. This notification destination is, e.g., a network control apparatus (not shown) connected to the logical network together with the network control apparatus 101A. In some cases, the network control apparatus of notification destination of the connection acceptance may not exist.

As described above, the network control apparatus 101A is a receiving apparatus. The network control apparatus 101A outputs, to the storage medium 102, the first destination information input to the network control apparatus 101B serving as a transmitting apparatus (step S405), and receives data transmitted from the network control apparatus 101B. The network control apparatus 101A receives the second destination information from the storage medium 102 (step S408). If the first destination information matches the second destination information (YES in step S409), data reception from the Internet 100 is limited (step S413).

In step S415, it is determined using the logical network connection setting information read out in step S408 whether to connect to the logical network. If the network control apparatus has not connected to the logical network corresponding to the logical network connection setting information, connection processing is performed. If the network control apparatus has already connected to the logical network corresponding to the logical network connection setting information, no connection processing is performed. In this case, pieces of connection setting information for accepting a logical network are compared (addresses (of the network control apparatus 101A in the connection setting information) are compared) to determine whether the target logical network is identical to the connected one. Whether to connect to the logical network may also be determined by inputting an instruction about connection of connection setting information to the control unit 301 from a user interface or another program.

If it is determined in step S415 to connect to the logical network using the logical network connection setting information read out in step S408, the process proceeds to step S416. If it is determined in step S415 not to connect to the logical network using the logical network connection setting information, the process ends.

In step S416, connection to the logical network starts using the logical network connection setting information read out in step S408, and the process proceeds to step S417. The logical network connection setting information includes information such as the IP address, port number, protocol, authentication method, and password of a node (in the above-described example, the network control apparatus 101A) permitted to connect to the logical network. In other words, the connection setting information is destination information representing a destination permitted to connect to the logical network when transmitting connection permission.

In step S417, the start of connection to the logical network is notified, and the process ends. A node or processor which requires logical network connection start information is notified of the start. The notification destination may also be the unicast address of a node (e.g., network control apparatus) already connected to the logical network, the unicast address of a node which requires the logical network connection start information, or a multicast address for advertising the logical network connection start information. As the connection start notification, connection start information is advertised to the Internet 100 to which the network control apparatus 101B is connected.

More specifically, the network control apparatus 101B is a transmitting apparatus, and outputs, to the storage medium 102, the received first destination information to another transmitting apparatus, similar to the network control apparatus 101A (step S405). The network control apparatus 101B receives the second destination information from the storage medium 102 (step S408). If the first destination information does not match the second destination information (NO in step S409), the network control apparatus 101B transmits a logical network connection request (transmission data) including the second destination information (step S417). When the first destination information does not match the second destination information, this means that the destination information input to a network control apparatus in step S408 is not one output (step S405) from the network control apparatus itself that has received the destination information.

Upon accepting the logical network connection start notification from the network control apparatus 101B, the network control apparatus 101A and a network control apparatus (not shown) which are connected to the logical network recognize the IP address (unicast address) of the network control apparatus 101B. The logical network connection start notification can be accepted till the end of accepting connection to the logical network in step S413 after the start of accepting the connection in step S406.

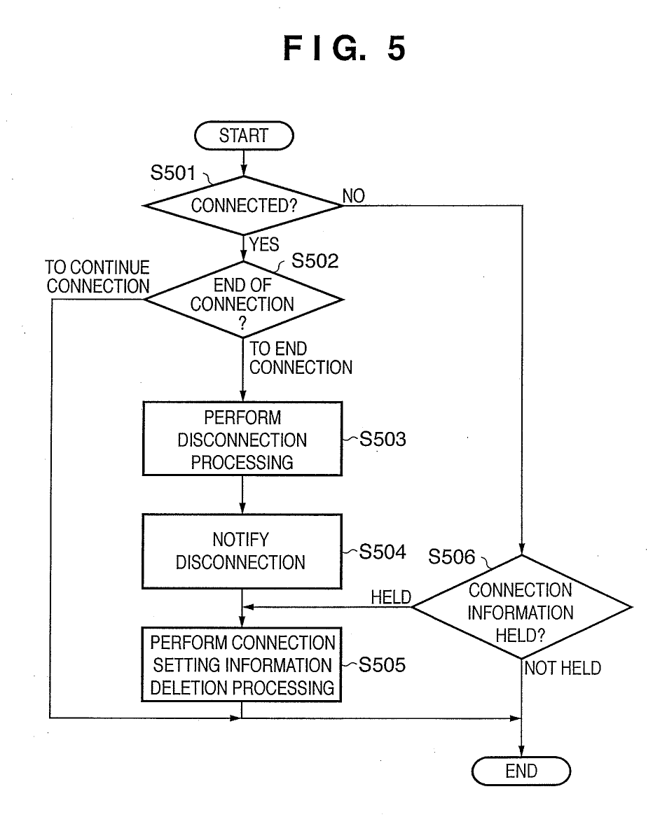

A sequence upon detecting disconnection of a storage medium according to the first embodiment will be explained with reference to the flowchart of FIG. 5. FIG. 5 shows part of a computer program stored in the HDD 209 or FDD 210. The computer CPU 201 reads out the program from the HDD 209 or FDD 210, and executes an operation corresponding to the flowchart of FIG. 5. The HDD 209 or FDD 210 is a storage medium which stores the program so that the CPU 201 can read it out.

In step S501, it is determined whether a logical network associated with the storage medium 102, disconnection of which has been detected, is connected. If it is determined in step S501 that the logical network associated with the storage medium 102, disconnection of which has been detected, is connected, the process proceeds to step S502. If it is determined in step S501 that the logical network associated with the storage medium 102, disconnection of which has been detected, is not connected, the process proceeds to step S506.

In step S502, it is determined whether to end the connection of the logical network associated with the storage medium 102, disconnection of which has been detected. If it is set from a user interface or another program during connection of the storage medium 102 to continue connection of the logical network, the connection continues; otherwise, the connection ends. Connection setting information may also be deleted by inputting an instruction about deletion of the connection setting information after the storage medium 102 is disconnected. This determination may also be omitted to end the connection unconditionally. If it is determined in step S502 to end the connection of the logical network associated with the storage medium 102, disconnection of which has been detected, the process proceeds to step S503. If it is determined in step S502 to continue the connection of the logical network associated with the storage medium 102, disconnection of which has been detected, the process ends.

In step S503, the logical network associated with the storage medium 102, disconnection of which has been detected, is disconnected, and the process proceeds to step S504.

In step S504, the disconnection of the logical network associated with the storage medium 102, disconnection of which has been detected, is notified, and the process proceeds to step S505. A node or processor which requires logical network disconnection information is notified of the disconnection. The notification destination may be the unicast address of a node (e.g., the network control apparatus 101A) connected to the logical network, the unicast address of a node which requires the logical network disconnection information, or a multicast address for advertising the logical network disconnection information.

In step S505, connection setting information of the logical network associated with the storage medium 102, disconnection of which has been detected, is deleted from the information holding unit 304, and the process ends. The network control apparatus 101B deletes connection setting information read out in step S408.

In step S506, it is determined whether the information holding unit 304 holds the connection setting information of the logical network associated with the storage medium 102, disconnection of which has been detected. Even when the logical network is disconnected owing to an error or from a user interface or another program, the connection setting information of the logical network is not always deleted. Hence, if the connection setting information of the logical network is not deleted, it is deleted. If the connection setting information of the logical network is deleted by any means, no logical network setting information exists in step S506.

If it is determined in step S506 that the information holding unit 304 holds the connection setting information of the logical network associated with the storage medium 102, disconnection of which has been detected, the process proceeds to step S505. If it is determined in step S506 that the information holding unit 304 does not hold the connection setting information of the logical network associated with the storage medium 102, disconnection of which has been detected, the process ends.

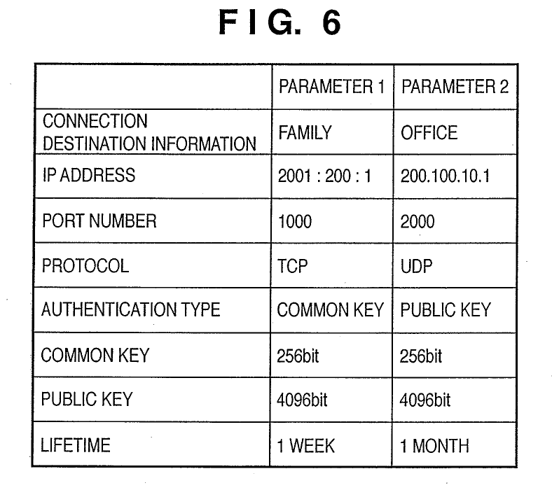

Information stored in the storage medium 102 according to the first embodiment will be explained with reference to FIG. 6.

In FIG. 6, the storage medium 102 stores connection setting information of two logical networks. The number of connection setting information stored in the storage medium is not limited, and the storage medium may also store an arbitrary number (including 0) of connection setting information.

In FIG. 6, connection destination information includes information representing a logical network. In the first embodiment, a logical network for sharing a variety of services within a family is defined as a family, and a logical network for sharing a variety of services within a company is defined as an office.

In FIG. 6, the IP address is that of a connection destination (network control apparatus 101A) permitted to connect to a logical network. In the first embodiment, an IPv4 address and IPv6 address are stored as IP addresses. However, the IP address is not limited to them, and an IP address in another format may also be stored.

In FIG. 6, the port number is that of a connection destination (network control apparatus 101A) permitted to connect to a logical network.

In FIG. 6, the protocol is a transport protocol used when communicating with a connection destination permitted to connect to a logical network. TCP and UDP can be stored as transport protocols. However, the transport protocol is not limited to them, and another transport protocol (e.g., Stream Control Transmission Protocol (SCTP)) may also be stored.

In FIG. 6, the authentication type is an authentication method/encryption method used when communicating with a connection destination permitted to connect to a logical network. An authentication method/encryption method using a common key, and an authentication method/encryption method using a public key are stored. However, the authentication method/encryption method is not limited to them, and another authentication method/encryption method and algorithm may also be stored.

In FIG. 6, the common key is a 256-bit common key used for authentication and encryption with a connection destination permitted to connect to a logical network. The common key is not limited to this, and a common key having an arbitrary length may also be stored.

In FIG. 6, the public key is a 4,096-bit public key used for authentication and encryption with a connection destination permitted to connect to a logical network. The public key is not limited to this, and a public key having an arbitrary length may also be stored.

In FIG. 6, the lifetime is the valid time of a connection parameter. During the lifetime, connection to a connection destination permitted to connect to a logical network is possible. In the first embodiment, one week and one month are set as lifetimes. However, the lifetime is not limited to them, and an arbitrary lifetime or infinite lifetime may also be stored.

In addition to FIG. 6, a logical network parameter (e.g., an address or ID on a logical network or path information on a logical network) may also be stored.

In the first embodiment, connection acceptance information includes authentication information corresponding to connection setting information. The connection acceptance information may also include an IP address, port number, lifetime, logical network parameter, and the like. The authentication information in the connection acceptance information includes the authentication type, common key, and public key in FIG. 6. The authentication information of the connection acceptance information is paired with connection setting information.

The first embodiment can facilitate setting of connection setting information necessary to connect to a logical network, and simplify complicated processing at the start of connection to a logical network.

By connecting the storage medium 102, network settings can be easily generated and deleted, and connection/disconnection to/from a logical network can be easily done. By applying the first embodiment to a device (e.g., digital camera or printer) having a poor user interface, the user can easily utilize the device while avoiding a complicated parameter setting phase.

### Second Embodiment

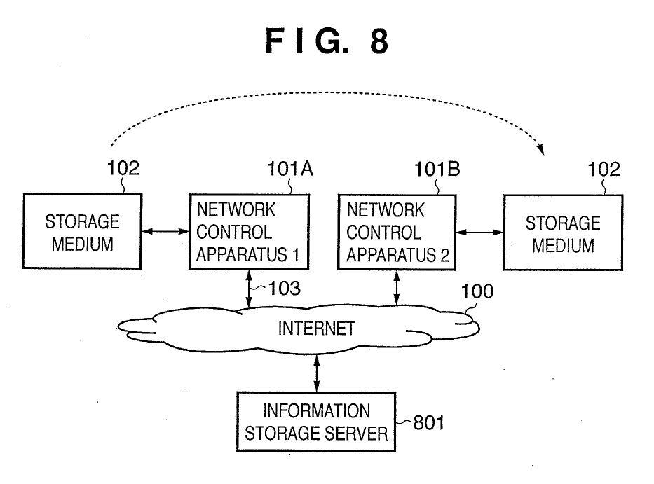

The configuration of a network system according to the second embodiment will be described with reference to FIG. 8. In the second embodiment, the basic configuration is common to that in the first embodiment. A difference of the second embodiment from the first embodiment will be described.

An information storage server 801 manages part of information in a storage medium 102. Since the information storage server 801 stores part of information in the storage medium 102 in the first embodiment, the information amount stored in the storage medium 102 can be reduced. The second embodiment exemplifies one information storage server 801. However, the number of information storage servers 801 is not limited to one, and a plurality of information storage servers 801 may also be distributed via a network (e.g., peer-to-peer connection using a distributed hash table).

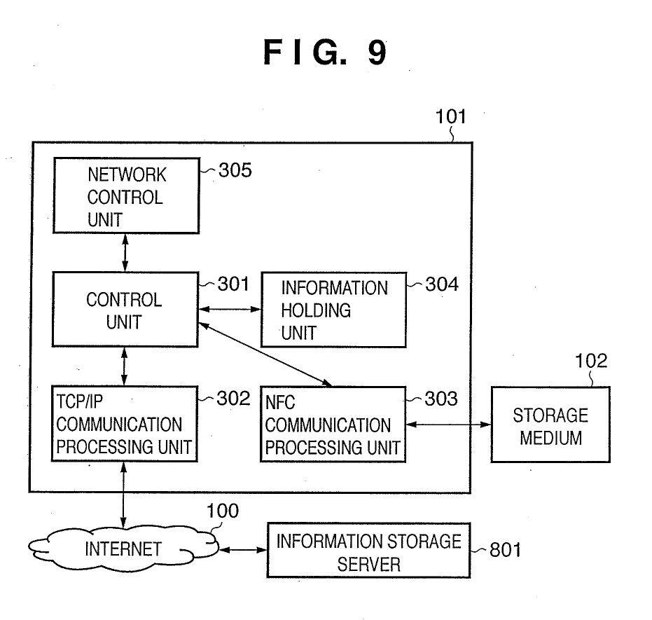

A module configuration in network control apparatuses (receiving apparatus, transmitting apparatus, and communication apparatus) 101A and 101B according to the second embodiment will be explained with reference to FIG. 9.

In FIG. 9, a control unit 301 communicates with the information storage server 801 via a TCP/IP communication processing unit 302 using information in the storage medium 102. The information storage server 801 can be designated using unicast which directly designates the information storage server 801, multicast which designates information storage servers, or anycast for the information storage server 801.

By associating the storage medium 102 with the information storage server 801 in advance, the information storage server 801 can be accessed from information stored in the storage medium 102. The storage medium 102 stores the address of the information storage server. When directly accessing the server, this address is an IP address.

According to the second embodiment, in step S405 of FIG. 4, the storage medium 102 stores part of generated logical network connection setting information, and a parameter ID. The storage medium stores the address of the information storage server in advance. Information stored in the storage medium 102 will be described later. The information storage server 801 stores part of the generated logical network connection setting information and the ID. Information stored in the information storage server 801 will be described later.

In step S408, part of the logical network connection setting information, the address of the information storage server 801, and the parameter ID which are stored in the storage medium 102 are read out. The ID is transmitted to the information storage server 801 associated with the storage medium 102. The information storage server 801 searches for a parameter corresponding to the ID, and sends back part of the logical network connection setting information. In step S416, connection starts using the connection setting information sent back from the information storage server 801.

In step S412, part of the logical network connection setting information and the ID are deleted from the storage medium 102 (identification information in the storage medium 102 is invalidated). Also, part of the logical network connection setting information that corresponds to the ID is deleted from the information storage server 801. That is, the TCP/IP communication processing unit 302 receives connection setting information (second destination information) from the information storage server 801 serving as a device on Internet (network) 100 (step S408) If the connection setting information (second destination information) received from the information storage server 801 matches connection setting information (first destination information) output in step S405, the control unit 301 invalidates the connection setting information stored in the information storage server 801 (step S412). If the connection setting information (second destination information) received from the information storage server matches the connection setting information (first destination information) output in step S405, the control unit 301 limits reception of transmission data by the TCP/IP communication processing unit 302 (step S413).

Also in the second embodiment, when the control unit 301 sets the port number of a home router in step S406, the port number setting of the UPnP Internet Gateway Device is deleted in step S406. The deletion is achieved by DeletePortMapping in the UPnP Internet Gateway Device. If NAT traversal of the home router by STUN or the like is set in step S406, the processing to set NAT traversal of the home router ends in step S411. That is, when the information (first destination information) output in step S405 matches the information (second destination information) received in step S408, transfer of transmission data to (the TCP/IP communication processing unit 302 of) the network control apparatus 101A via the home router is limited. The home router is a device on the network.

Also in the second embodiment, the network control apparatus 101B is a transmitting apparatus, and outputs, to the storage medium 102, the received first destination information to another transmitting apparatus (step S405). The network control apparatus 101B receives the second destination information from the information storage server 801 (step S408). If the first destination information does not match the second destination information (NO in step S409), the network control apparatus 101B transmits a logical network connection request (transmission data) including the second destination information (step S417).

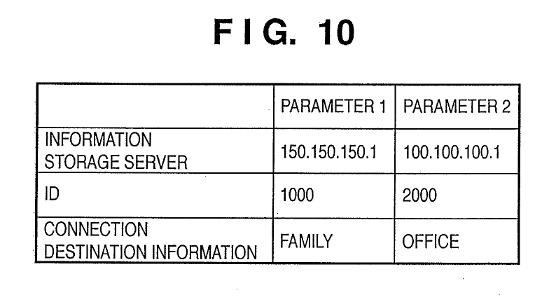

Information stored in the storage medium 102 according to the second embodiment will be explained with reference to FIG. 10.

In FIG. 10, the information storage server 801 represents the IP address of an information storage server associated with the storage medium 102. In FIG. 10, the ID is a parameter identifier used when extracting information from the information storage server 801. In FIG. 10, connection destination information includes information representing a logical network.

In the second embodiment, the number of connection setting information stored in the storage medium 102 is not limited, and the storage medium 102 may also store an arbitrary number (including 0) of connection setting information.

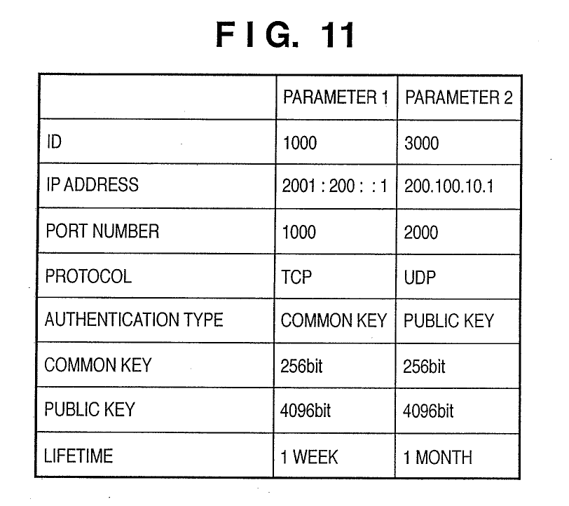

Information stored in the information storage server 801 according to the second embodiment will be explained with reference to FIG. 11.

As an example in the second embodiment, the IP address of the information storage server 801 which holds information in FIG. 11 is 150.150.150.1. Information stored in the storage medium 102 shown in FIG. 10 and that stored in the information storage server 801 shown in FIG. 11 are associated with each other.

In FIG. 11, the ID is a parameter identifier used when extracting information from the information storage server 801. The ID in FIG. 11 corresponds to that in FIG. 10.

In FIG. 11, the definitions of the IP address, port number, protocol, authentication type, common key, public key, and lifetime are common to those in FIG. 6.

### Third Embodiment

The configuration of a network system according to the third embodiment will be described with reference to FIG. 8. In the third embodiment, the basic configuration is common to that in the second embodiment. A difference of the third embodiment from the second embodiment will be described.

A storage medium 102 and information storage server 801 can be associated with each other by associating a network control apparatus 101A with the information storage server 801 in advance.

In FIG. 9, an information holding unit 304 holds the address of the information storage server 801 associated with generated connection setting information. A control unit 301 stores the address of the associated information storage server 801 in the storage medium 102. With this arrangement, the storage medium 102 can be associated with the information storage server 801.

According to the third embodiment, in step S405 of FIG. 4, the storage medium 102 stores part of logical network connection setting information, the address of the information storage server 801, and a parameter ID (FIG. 10). The information storage server 801 stores part of the logical network connection setting information and the ID (FIG. 11).

In step S408, part of the logical network connection setting information, the address of the information storage server 801, and the ID which are stored in the storage medium 102 are read out. The ID is transmitted to the information storage server 801. The information storage server 801 executes search based on the ID, and sends back part of the logical network connection setting information. In step S416, connection starts using the connection setting information sent back from the information storage server 801.

In step S412, part of the logical network connection setting information, the address of the information storage server 801, and the ID which are stored in the storage medium 102 are deleted. Also, part of the logical network connection setting information which is stored in the information storage server 801 in correspondence with the ID is deleted. That is, if the connection setting information (second destination information) received from the information storage server 801 matches connection setting information (first destination information) output in step S405, the connection setting information (second destination information) stored in the information storage server 801 is invalidated. The information storage server 801 is a device on Internet 100. If the connection setting information (second destination information) received from the information storage server 801 matches the connection setting information (first destination information) output in step S405, the control unit 301 limits reception of transmission data by a TCP/IP communication processing unit 302 (step S413).

Also in the third embodiment, when the control unit 301 sets the port number of a home router in step S406, the port number setting of the UPnP Internet Gateway Device is deleted in step S406. The deletion is achieved by DeletePortMapping in the UPnP Internet Gateway Device. If NAT traversal of the home router by STUN or the like is set in step S406, the processing to set NAT traversal of the home router ends in step S411. That is, when the information (first destination information) output in step S405 matches the information (second destination information) received in step S408, transfer of transmission data to (the TCP/IP communication processing unit 302 of) the network control apparatus 101A via the home router serving as a device on the network is limited.

Also in the third embodiment, a network control apparatus 101B is a transmitting apparatus, and outputs, to the storage medium 102, the received first destination information to another transmitting apparatus (step S405). The network control apparatus 101B receives the second destination information from the information storage server 801 (step S408). If the first destination information does not match the second destination information (NO in step S409), the network control apparatus 101B transmits a logical network connection request (transmission data) including the second destination information (step S417).

### Fourth Embodiment

In the above-described form, information is output from the network control apparatus 101A to the storage medium 102, and the information is input from the storage medium 102 to the network control apparatus 101B. However, the medium which mediates transfer of information from the network control apparatus 101A to the network control apparatus 101B is not limited to the storage medium. For example, it is also possible to print information from the network control apparatus 101A on paper or the like, and optically read and recognize the information on paper or the like by the network control apparatus 101B. When printing on paper or the like, information may also be printed in an encoded form such as a barcode.

When the network control apparatus 101B is a portable device, information can also be transferred directly from the network control apparatus 101A to the network control apparatus 101B by short distance wireless communication without the mediacy of the storage medium 102. This is effective when the network control apparatus 101B is moved apart from the network control apparatus 101A.

The object of the present invention is also achieved by supplying a storage medium which stores software program codes for implementing the functions of the above-described embodiments to a system or apparatus, and reading out and executing the program codes stored in the storage medium by the computer (or the CPU or MPU) of the system or apparatus. In this case, the program codes read out from the storage medium implement the functions of the above-described embodiments, and the storage medium which stores the program codes constitutes the present invention.

The storage medium for supplying the program codes includes a flexible disk, hard disk, optical disk, magnetooptical disk, CD-ROM, CD-R, nonvolatile memory card, ROM, and DVD.

The present invention is not limited to a case where the functions of the above-described embodiments are implemented when the computer executes the readout program codes. Also, the present invention includes a case where an OS (Operating System) or the like running on the computer performs part or all of actual processing on the basis of the instructions of the program codes and thereby implements the functions of the above-described embodiments.

Furthermore, the present invention includes the following case. That is, the program codes read out from the storage medium are written in the memory of a function expansion board inserted into the computer or the memory of a function expansion unit connected to the computer. Then, the CPU of the function expansion board or function expansion unit performs part or all of actual processing on the basis of the instructions of the program codes, thereby implementing the functions of the above-described embodiments.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-315714, filed Nov. 22, 2006, which is hereby incorporated by reference herein in its entirety.

What is claimed is:

1. A receiving apparatus comprising:
a receiving unit adapted to receive, via a transmission medium, transmission data transmitted from a transmitting apparatus;
a setting unit adapted to set, in a transferring device on the transmission medium, first identification information to be used by the transferring device to identify transmission data to be transferred to said receiving unit, and second identification information to be used by said receiving unit to identify transmission data transmitted to said receiving unit; and
an output unit adapted to output the received first identification information to be inputted to the transmitting apparatus via a medium different from the transmission medium,
wherein said receiving unit identifies, based on the second identification information, transmission data which is assigned with the second identification information and transferred by the transferring device after transmitted from the transmitting apparatus that has inputted the first identification information, and said receiving unit receives the identified transmission data.

2. The apparatus according to claim 1, wherein said receiving unit comprises an input unit adapted to input third identification information, and a limitation unit adapted to limit reception of the transmission data by said receiving unit in a case where the first identification information matches the third identification information.

3. The apparatus according to claim 1, wherein said setting unit comprises an input unit adapted to input third identification information, and a limitation unit adapted to limit transfer of the transmission data from the transferring device to said receiving unit in a case where the first identification information matches the third identification information.

4. The apparatus according to claim 1, wherein said setting unit comprises a limitation unit adapted to limit reception of the transmission data by said receiving unit in a case where third identification information received by said receiving unit from the transferring device matches the first identification information.

5. A receiving apparatus which comprises a receiving unit adapted to receive, via a transmission medium, transmission data transmitted from a transmitting apparatus, and receives, by said receiving unit from a communication apparatus on the transmission medium, identification information used by a transferring device on the transmission medium to identify transmission data to be transferred to said receiving unit, the apparatus further comprising:
an output unit adapted to output the received identification information to be inputted to the transmitting apparatus via a medium different from the transmission medium,
wherein said receiving unit receives the transmission data transferred by the transferring device after transmitted from the transmitting apparatus that has inputted the identification information.

6. The apparatus according to claim 5, wherein said receiving unit comprises an input unit adapted to input second identification information, and a limitation unit adapted to limit reception of the transmission data by said receiving unit in a case where the second identification information input by said input unit matches the identification information used by the transferring device to identify the transmission data to be transferred to said receiving unit.

7. The apparatus according to claim 5, wherein said receiving unit comprises an input unit adapted to input second identification information, and a limitation unit adapted to limit transfer of the transmission data from a device on a network to said receiving unit in a case where the second identification information input by said input unit matches the identification information used by the transferring device to identify the transmission data to be transferred to said receiving unit.

8. The apparatus according to claim 5, wherein said receiving unit comprises a limitation unit adapted to limit reception of the transmission data by said receiving unit in a case where second identification information received via the transferring device matches the identification information used by the transferring device to identify the transmission data to be transferred to said receiving unit.

9. A receiving method executed in a receiving apparatus, the method comprising:
receiving, via a transmission medium, transmission data transmitted from a transmitting apparatus;
setting, in a transferring device on the transmission medium, first identification information to be used by the transferring device to identify transmission data to be transferred to the receiving apparatus, and second identification information to be used by said receiving unit to identify transmission data transmitted to the receiving apparatus; and
outputting the received first identification information to be inputted to the transmitting apparatus via a medium different from the transmission medium,
wherein in the receiving step, transmission data which is assigned with the second identification information and transferred by the transferring device after transmitted from the transmitting apparatus that has inputted the first identification information is identified based on the second identification information and the identified transmission data is received.

10. The method according to claim 9, wherein the receiving step comprises an input step of inputting third identification information, and a limitation step of limiting reception of the transmission data in a case where the first identification information matches the third identification information.

11. The method according to claim 9, wherein the setting step comprises an input step of inputting third identification information, and a limitation step of limiting transfer of the transmission data from the transferring device to the receiving apparatus in a case where the first identification information matches the third identification information.

12. The method according to claim 9, wherein the setting step comprises a limitation step of limiting transfer of the transmission data from the transferring device to the receiving apparatus in a case where third identification information received from the transferring device matches the first identification information.

13. A receiving method executed in a receiving apparatus which receives identification information from a communication apparatus on a transmission medium, wherein the identification information is used by a transferring device on the transmission medium to identify transmission data to be transferred to the receiving apparatus, the method comprising:
receiving, via the transmission medium, transmission data transmitted from a transmitting apparatus; and
outputting the received identification information to be inputted to the transmitting apparatus via a medium different from the transmission medium,
wherein in the receiving step, the transmission data which is transferred by the transferring device after transmitted from the transmitting apparatus that has inputted the identification information is received.

14. The method according to claim 13, wherein the receiving step comprises an input step of inputting second identification information, and a limitation step of limiting reception of the transmission data in a case where the second identification information input in the input step matches the identification information used by the transferring device to identify the transmission data to be transferred to the receiving apparatus.

15. The method according to claim 13, wherein the receiving step comprises an input step of inputting second identification information, and a limitation step of limiting transfer of the transmission data from the transferring device to the receiving apparatus in a case where the second identification information input in the input step matches the identification information used by the transferring device to identify the transmission data to be transferred to the receiving apparatus.

16. The method according to claim 13, wherein the receiving step comprises a limitation step of limiting transfer of the transmission data from the transferring device to the receiving apparatus in a case where second identification information received via the transferring device matches the identification information used by the transferring device to identify the transmission data to be transferred to the receiving apparatus.

17. A computer program stored in a storage medium, for causing a computer to execute the receiving method described in claim 9.

18. The program according to claim 17, wherein the setting step comprises an input step of inputting third identification information, and a limitation step of limiting transfer of the transmission data from the transferring device to the receiving apparatus in a case where the first identification information matches the third identification information.

19. A computer program stored in a storage medium, for causing a computer to execute the receiving method described in claim 13.

20. The program according to claim 19, wherein the receiving step comprises an input step of inputting second identification information, and a limitation step of limiting transfer of the transmission data from the transferring device to the receiving apparatus in a case where the second identification information input in the input step matches the identification information used by the transferring device to identify the transmission data to be transferred to the receiving apparatus.
